(19) United States
(12) Patent Application Publication
(10) Pub. No.: US 2008/0050863 A1
(43) Pub. Date: Feb. 28, 2008

(54) SEMICONDUCTOR STRUCTURE INCLUDING MULTIPLE STRESSED LAYERS

(75) Inventors: William K. Henson, Peekskill, NY (US); Dureseti Chidambarrao, Weston, CT (US); Yaocheng Liu, Elmsford, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: International Business Machines Corporation, Armonk, NY (US)

(21) Appl. No.: 11/467,721

(22) Filed: Aug. 28, 2006

(51) Int. Cl. H01L 21/84

(52) U.S. Cl. 438/151

(57) ABSTRACT

A semiconductor structure and methods for fabricating the semiconductor structure include a gate electrode located over a channel region within a semiconductor substrate and a spacer layer adjacent the gate electrode. The spacer layer extends vertically above the gate electrode. The semiconductor structure also includes a first stressed layer having a first stress located over the gate electrode and a second stressed layer having a second stress different than the first stress located over the first stressed layer. At least a portion of the first stressed layer is laterally contained by the spacer layer. At least a portion of the second stressed layer is not laterally contained by the spacer layer.

### BACKGROUND OF THE INVENTION

1. Field of the Invention

The invention relates generally to mechanical stress within semiconductor structures. More particularly, the invention relates to optimized mechanical stress within semiconductor structures.

2. Description of the Related Art

Recent trends within semiconductor device fabrication have exploited the use of mechanical stress within a semiconductor device channel for purposes of modifying charge carrier mobility within the semiconductor device channel. Often, one of a tensile mechanical stress and a compressive mechanical stress within an n-field effect transistor device channel provides for an enhanced electron charge carrier mobility within the n-field effect transistor device channel. Similarly, the other of the tensile mechanical stress and the compressive mechanical stress within a p-field effect transistor device channel provides for an enhanced hole charge carrier mobility within the p-field effect transistor device channel. Such a favorable complementary mechanical stress effect may arise for n-field effect transistor devices and p-field effect transistor devices fabricated using the same or different crystallographic orientation substrates that have the same or different current flow directions. In general, enhanced charge carrier mobility provides for enhanced semiconductor device performance.

Under appropriate circumstances, the use of a mechanical stress within a semiconductor device channel provides a desirable enhancement of charge carrier mobility within a semiconductor device. However, it is desirable to provide semiconductor structures wherein a semiconductor device channel when mechanically stressed is stressed to optimize a desirable charge carrier mobility enhancement.

Semiconductor structure and semiconductor device dimensions are certain to continue to decrease. As a result of such decreases, desirable are semiconductor structures and semiconductor devices that optimally take advantage of a mechanical stress effect for charge carrier mobility enhancement. It is towards the foregoing object that the instant invention is directed.

### SUMMARY OF THE INVENTION

The invention includes a semiconductor structure and methods for fabricating the semiconductor structure. The semiconductor structure and the related methods include: (1) a first stressed layer having a first stress located over a gate electrode located over a channel within a semiconductor substrate, where at least a portion of the first stressed layer is laterally contained by a spacer layer that is adjacent to and rises vertically above the gate electrode; and (2) a second stressed layer having a second stress different than the first stress located over the first stressed layer, where at least a portion of the second stressed layer is not laterally contained by the spacer layer. A particular combination of the first stress and the second stress provides for a more optimized stress profile within the channel region of the semiconductor substrate for a particular crystallographic orientation of the semiconductor substrate.

A semiconductor structure in accordance with the invention includes a semiconductor substrate including a gate electrode located over a channel region within the semiconductor substrate, and a spacer layer located adjacent a sidewall of the gate electrode and rising vertically above the gate electrode. This particular semiconductor structure also includes a first stressed layer having a first stress located over the gate electrode. At least a portion of the first stressed layer is laterally contained by the spacer layer. This particular semiconductor structure also includes a second stressed layer having a second stress different than the first stress located over the first stressed layer. At least a portion of the second stressed layer is not laterally contained by the spacer layer.

A method in accordance with the invention includes forming a gate electrode over a channel region within a semiconductor substrate and forming a spacer layer adjacent the gate electrode and rising vertically above the gate electrode. This particular method also includes forming a first stressed layer having a first stress over the gate electrode. At least a portion of the first stressed layer is laterally contained by the spacer layer. This particular method also includes forming a second stressed layer having a second stress different than the first stress over the first stressed layer. At least a portion of the second stressed layer is not laterally contained by the spacer layer.

Another method in accordance with the invention includes forming over a channel region within a semiconductor substrate a gate electrode stack comprising a gate electrode, a sacrificial layer located upon the gate electrode and a spacer layer located adjacent a sidewall of the gate electrode and the sacrificial layer. This particular method also includes stripping the sacrificial layer from the gate electrode so that the spacer layer rises vertically above the gate electrode. This particular method also includes forming a first stressed layer having a first stress over the gate electrode. At least a portion of the first stressed layer is laterally contained by the spacer layer. The particular method also includes forming a second stressed layer having a second stress different than the first stress over the first stressed layer. At least a portion of the second stressed layer is not laterally contained by the spacer layer.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1 to FIG. 9 show a series of schematic cross-sectional and plan-view diagrams illustrating the results of progressive stages in fabricating a field effect transistor in accordance with an embodiment of the invention.

FIG. 10 shows a graph of Channel Stress and On Current Enhancement versus Field Effect Transistor Design for field effect transistors fabricated in accordance with the invention.

### DESCRIPTION OF THE PREFERRED EMBODIMENT

The invention, which comprises a semiconductor structure with an enhanced mechanical stress effect and methods for fabricating the semiconductor structure with the enhanced mechanical stress effect, is understood within the context of the description that follows. The description that follows is understood within the context of the drawings described above. Since the drawings are intended for descriptive purposes, the drawings are not necessarily drawn to scale.

FIG. 1 to FIG. 9 show a series of schematic cross-sectional and plan-view diagrams illustrating the results of progressive stages in fabricating a semiconductor structure in accordance with an embodiment of the invention.

FIG. 1 shows a semiconductor substrate 10 which includes a buried dielectric layer 12 located upon the semiconductor substrate 10 and a surface semiconductor layer 14 that is located upon part of the buried dielectric layer 12. An isolation region 16 is also located upon another part of the buried dielectric layer 12, and the isolation region 16 also adjoins the surface semiconductor layer 14. In an aggregate, the semiconductor substrate 10, the buried dielectric layer 12 and the surface semiconductor layer 14 comprise a semiconductor-on-insulator substrate.

The semiconductor substrate 10 may comprise any of several semiconductor materials. Non-limiting examples include silicon, germanium, silicon-germanium alloy, silicon carbide, silicon-germanium carbide alloy and compound (i.e., III-V and II-VI) semiconductor materials. Non-limiting examples of compound semiconductor materials include gallium arsenide, indium arsenide and indium phosphide semiconductor materials. Typically, the semiconductor substrate 10 has a thickness from about 0.5 to about 1.5 mm.

Similarly, the buried dielectric layer 12 may comprise any of several dielectric materials. Non-limiting examples include oxides, nitrides and oxynitrides, particularly of silicon. However, oxides, nitrides and oxynitrides of other elements are not excluded. The buried dielectric layer 12 may comprise a crystalline or a non-crystalline dielectric material. Crystalline dielectric materials are generally highly preferred. The buried dielectric layer 12 may be formed using any of several methods. Non-limiting examples of methods include ion implantation methods, thermal or plasma oxidation or nitridation methods, chemical vapor deposition methods and physical vapor deposition methods. Typically, the buried dielectric layer 12 comprises an oxide of the semiconductor material from which is comprised the semiconductor substrate 10 (i.e., an oxide of the semiconductor substrate 10). Typically, the buried dielectric layer 12 has a thickness from about 200 to about 2000 angstroms.

The surface semiconductor layer 14 may comprise any of the several semiconductor materials from which the semiconductor substrate 10 may be comprised. The surface semiconductor layer 14 and the semiconductor substrate 10 may comprise either identical or different semiconductor materials with respect to chemical composition, crystallographic orientation, dopant concentration and dopant polarity. Typically, the surface semiconductor layer 14 has a thickness from about 100 to about 700 angstroms.

The semiconductor-on-insulator portion of the semiconductor structure that is illustrated in FIG. 1 (i.e., the semiconductor structure of FIG. 1 prior to forming the isolation region 16) may be fabricated using any of several methods. Non-limiting examples include layer lamination methods, layer transfer methods and separation by implantation of oxygen (SIMOX) methods.

The isolation region 16 may comprise any of several dielectric isolation materials from which is comprised the buried dielectric layer 12. Again, these dielectric materials typically comprise oxides, nitrides and oxynitrides of silicon, although oxides, nitrides and oxynitrides of other elements are not excluded. These dielectric isolation materials may be formed using methods that are analogous or equivalent to the methods that are used for forming the buried dielectric layer 12.

To form completely the semiconductor structure of FIG. 1, one first starts with the semiconductor-on-insulator substrate that comprises the semiconductor substrate 10, the buried dielectric layer 12 and a blanket precursor layer to the surface semiconductor layer 14. The blanket precursor layer to the surface semiconductor layer 14 is then patterned to yield gaps wherein it is desired to locate the isolation region 16. Subsequently, the isolation region 16 is formed and located into the gaps while using a blanket layer deposition and planarizing method. Suitable types of planarization methods include mechanical planarizing methods and chemical mechanical polish planarizing methods. Alternative methods for forming the semiconductor structure of FIG. 1 may also be used.

Although the instant embodiment illustrates the invention within the context of a semiconductor-on-insulator substrate comprising: (1) the semiconductor substrate 10; (2) the buried dielectric layer 12 located thereupon; and (3) the surface semiconductor layer 14 and the isolation region 16 located further thereupon, neither the instant embodiment nor the invention in general is so limited. Rather, the instant embodiment may alternatively be practiced using a bulk semiconductor substrate (that would otherwise result from absence of the buried dielectric layer 12 under circumstances where the semiconductor substrate 10 and the surface semiconductor layer 14 have identical chemical composition and crystallographic orientation). The instant embodiment also contemplates use of a hybrid orientation (HOT) substrate as a semiconductor substrate. A hybrid orientation substrate comprises multiple crystallographic orientation regions within a single semiconductor substrate.

FIG. 2 shows (in cross-section) a field effect transistor T located within and upon the surface semiconductor layer 14 of the semiconductor-on-insulator substrate that is illustrated in FIG. 1. The field effect transistor comprises: (1) a gate dielectric 18 located upon the surface semiconductor layer 14; (2) a gate electrode 20 located upon the gate dielectric 18; (3) a sacrificial layer 22 located upon the gate electrode 20; (4) a pair (in cross-section, but not in plan view) of spacer layers 24 located adjoining a pair of opposite sidewalls of the gate dielectric 18, the gate electrode 20 and the sacrificial layer 22; and (5) a pair of source/drain regions 26 located within the surface semiconductor layer 14. The pair of source/drain regions 26 is separated by a channel region that is aligned beneath the gate electrode 20. Each of the foregoing layers and structures may comprise materials and have dimensions that are conventional in the semiconductor fabrication art. Each of the foregoing layers and structures may also be formed using methods that are conventional in the semiconductor fabrication art.

The gate dielectric 18 may comprise generally conventional dielectric materials, such as oxides, nitrides and oxynitrides of silicon that have a dielectric constant from about 4 to about 20, measured in vacuum. Alternatively, the gate dielectric 18 may comprise generally higher dielectric constant dielectric materials having a dielectric constant from about 20 to at least about 100, also measured in a vacuum. Such higher dielectric constant dielectric materials may include, but are not limited to hafnium oxides, hafnium silicates, titanium oxides, barium-strontium-titantates (BSTs) and lead-zirconate-titanates (PZTs). The gate dielectric 18 may be formed using any of several methods that are appropriate to the material(s) of composition of the gate dielectric 18. Included, but not limiting are: thermal or plasma oxidation or nitridation methods, chemical vapor deposition methods and physical vapor deposition methods. Typically, the gate dielectric 18 comprises a thermal silicon oxide dielectric material that has a thickness from about 10 to about 70 angstroms.

The gate electrode 20 may comprise materials including, but not limited to certain metals, metal alloys, metal nitrides and metal silicides, as well as laminates thereof and composites thereof. The gate electrode 20 may also comprise doped polysilicon and polysilicon-germanium alloy materials (i.e., having a dopant concentration from about 1e18 to about 1e22 dopant atoms per cubic centimeter) and polycide materials (doped polysilicon/metal silicide stack materials). Similarly, the foregoing materials may also be formed using any of several methods. Non-limiting examples include salicide methods, chemical vapor deposition methods and physical vapor deposition methods, such as, but not limited to evaporative methods and sputtering methods. Typically, the gate electrode 20 comprises a doped polysilicon material that has a thickness from about 150 to about 500 angstroms.

The sacrificial layer 22 may comprise any of several sacrificial materials. Dielectric sacrificial materials are most common, although conductor sacrificial materials and semiconductor sacrificial materials are also known. The dielectric sacrificial materials may include, but are not limited to oxides, nitrides and oxynitrides of silicon, but oxides, nitrides and oxynitrides of other elements again are not excluded. The dielectric sacrificial materials may be formed using any of the several methods that may be used for forming the buried dielectric layer 12. Typically, the sacrificial layer 22 comprises a silicon-germanium alloy dielectric or semiconductor sacrificial material that has a thickness from about 500 to about 900 angstroms.

The spacer layer 24 may comprise materials including, but not limited to conductor materials and dielectric materials. Conductor spacer materials are less common, but are nonetheless known. Dielectric spacer materials are more common. The spacer materials may be formed using methods analogous, equivalent or identical to the methods that are used for forming the sacrificial layer 22. The spacer layer 24 is also formed with the distinctive inward pointing spacer shape by using a blanket layer deposition and anisotropic etchback method that requires that the spacer layer 24 comprise a different spacer material than the sacrificial layer 22. Typically, the spacer layer 24 comprises a silicon nitride dielectric material when the sacrificial layer 22 comprises a silicon-germanium alloy material.

Finally, the pair of source/drain regions 26 comprises a generally conventional p or n conductivity type dopant that is appropriate to a polarity of a field effect transistor desired to be fabricated. As is understood by a person skilled in the art, the pair of source/drain regions 26 is formed using a two step ion implantation method. A first ion implantation process step within the method uses the gate electrode 20, absent the pair of spacer layers 24, as a mask to form a pair of extension regions each of which extends beneath the pair of spacer layers 24. A second ion implantation process step uses the gate electrode 20 and the pair of spacer layers 24 as a mask to form the larger contact region portions of the pair of source/drain regions 26, while simultaneously incorporating the pair of extension regions. Dopant levels are from about 1e19 to about 1 e21 dopant atoms per cubic centimeter within each of the pair of source/drain regions 26. Extension regions within the pair of source/drain regions 26 may under certain circumstances be more lightly doped than contact regions with the pair of source/drain regions, although such differential doping concentrations are not a requirement of the invention.

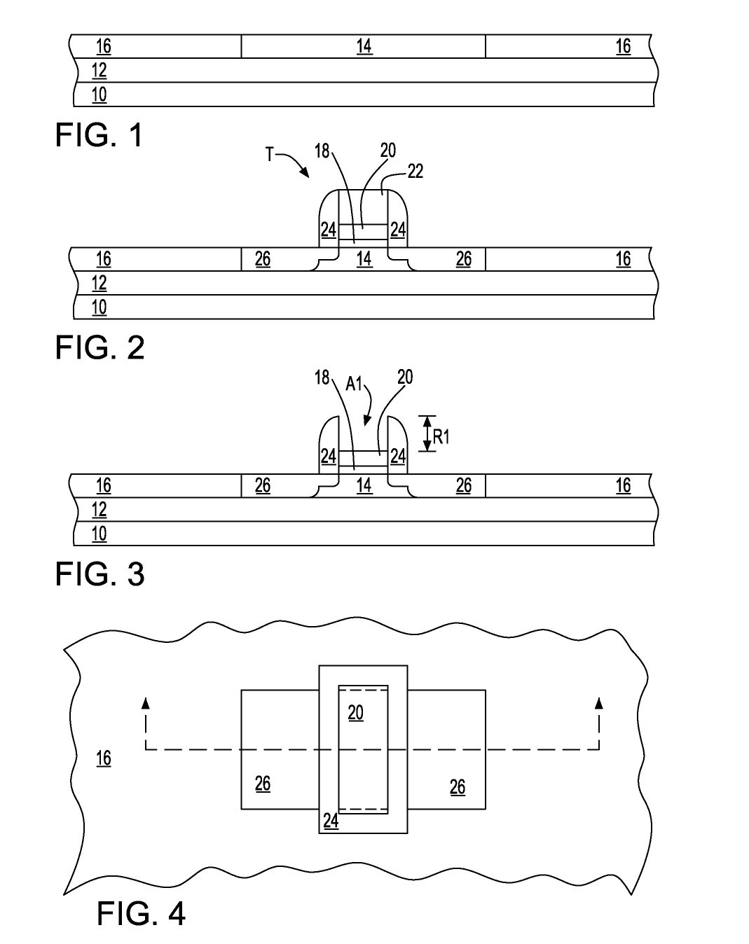

FIG. 3 shows the results of stripping the sacrificial layer 22 from the semiconductor structure of FIG. 1. As a result of stripping the sacrificial layer 22, an aperture A1 having a recess R1 from about 500 to about 900 angstroms (i.e., the same as the thickness of the sacrificial layer 22) is formed. At the bottom of the aperture is exposed the gate electrode 20. The sacrificial layer 22 may be stripped using methods and materials that are appropriate to the material of construction of the sacrificial layer 22. For a sacrificial layer 22 that comprises a silicon-germanium alloy semiconductor material, the sacrificial layer 22 may be stripped using either a wet chemical etch method and material or a dry plasma etch method and material. Such a wet chemical etch method and material typically includes aqueous ammonium hydroxide (i.e., 28 weight percent) and aqueous hydrogen peroxide (i.e., 30 weight percent) solution further diluted with deionized water. Weight percentage ratios are typically in a range from 1:1:5 to about 1:1.5:50 for aqueous ammonium hydroxide:aqueous hydrogen peroxide:deionized water. Alternatively, certain fluorine containing plasma etchant gas compositions etch a silicon-germanium alloy material selectively with respect to a silicon substrate material.

FIG. 4 shows a schematic plan-view diagram corresponding with the schematic cross-sectional diagram of FIG. 3.

FIG. 4 shows the isolation region 16, the source/drain regions 26, the spacer 24 and the gate electrode 20. Again, the spacer layer 24 encircles laterally the aperture A1 at the bottom of which is exposed the gate electrode 20.

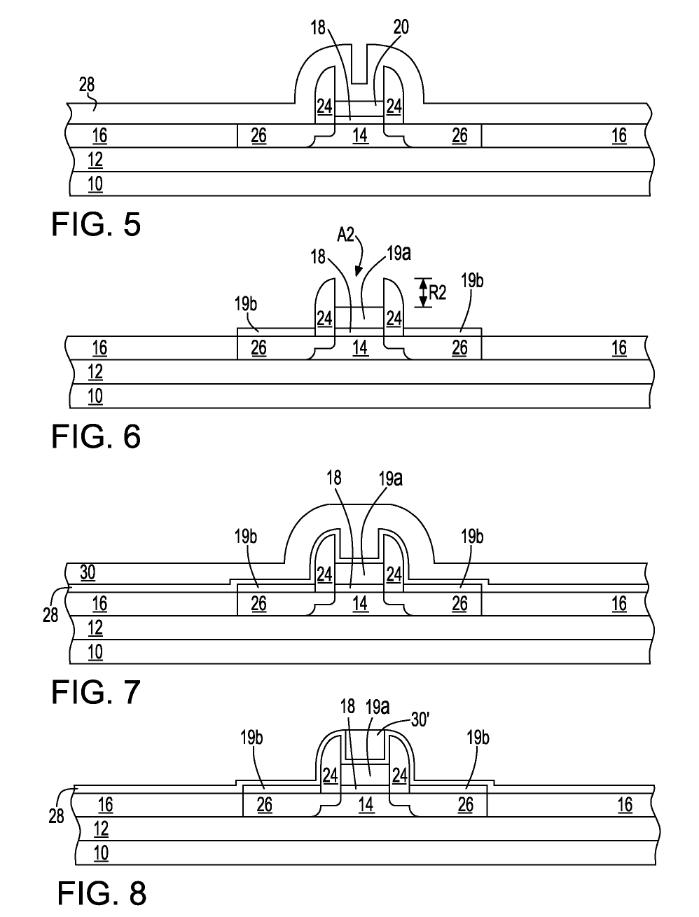

FIG. 5 shows a metal silicide forming metal layer 28 located upon the semiconductor structure of FIG. 4, and in particular contacting the gate electrode 20 which preferably comprises a silicon material. The metal silicide forming metal layer 28 may comprise any one or more of several metal silicide forming metals. Non-limiting examples of metal silicide forming metals include nickel, cobalt, platinum, titanium, tungsten, tantalum, vanadium, hafnium, erbium, ytterbium, and rhenium metal silicide forming metals. Typically, the metal silicide forming metal layer 28 has a thickness from about 70 to about 1000 angstroms and is otherwise intended to have a sufficient thickness such that upon thermal annealing with the gate electrode 20 when formed of a silicon material the gate electrode 20 is completely consumed to form a metal silicide gate electrode.

FIG. 6 first shows the results of thermally annealing the metal silicide forming metal layer 28 in the presence of the gate electrode 20 and the source/drain regions 26 to form: (1) a metal silicide gate electrode 19a; and (2) silicide layers 19b upon the source/drain region 26. An appropriate thermal annealing temperature and an appropriate thermal annealing time period are determined in accordance with a chemical composition of the metal silicide forming metal layer 28. A typical thermal annealing time period when using a cobalt metal silicide forming metal layer 28 is from about 0.25 to about 5 minutes and a thermal annealing temperature is from about 650 to about 750 degrees centigrade. Typically, a thickness of the metal silicide gate electrode 19a is from about 300 to about 500 angstroms. This thickness leaves an aperture A2 having a recess R2 from about 500 to about 900 angstroms from the top of the metal silicide gate electrode 19a to a tip of the spacer 24.

As is also illustrated by implication within the schematic cross-sectional diagram of FIG. 6, excess unreacted portions of the metal silicide forming metal layer 28 are stripped from the semiconductor structure of FIG. 5 after having formed the metal silicide gate electrode 19a and the silicide layers 19b. Excess unreacted portions of the metal silicide forming metal layer 28 may be stripped while using an appropriate stripping method and stripping material. Appropriate stripping methods and materials may include wet chemical stripping methods and materials, as well as dry plasma stripping methods and materials. Wet chemical stripping methods and materials are considerably more common. Wet chemical stripping methods and materials will typically use highly acidic aqueous solutions of composition appropriate to a particular metal silicide forming metal.

FIG. 7 first shows an optional liner layer 28 located upon the semiconductor structure of FIG. 6, and in particular located upon and covering the structures that comprise the field effect transistor. FIG. 7 also shows a first stressed material layer 30 located upon the optional liner layer 28. The first stressed material layer 30 has a first stress. When the field effect transistor whose schematic cross-sectional diagram is illustrated in FIG. 2 is an n-field effect transistor located upon a surface semiconductor layer 14 that comprises a <100> crystallographic current flow direction, the first stressed material layer 30 comprises a compressive stressed material.

The optional liner layer 28 is intended as useful when the spacer layer 24 and the first stressed material layer 30 comprise the same material, or alternatively materials that do not have an etch selectivity with respect to each other in a common etchant. Typically, when each of the spacer layer 24 and the first stressed material layer 30 comprises a silicon nitride material, the optional liner layer 28 comprises a silicon oxide material. The silicon oxide material which may be used to form the liner layer 28 may be formed using any of several methods. Non-limiting examples include chemical vapor deposition methods and physical vapor deposition methods.

The first stressed layer 30 may comprise any of several stressed materials. Non-limiting examples include stressed conductor materials, stressed semiconductor materials and stressed dielectric materials. Most common are stressed dielectric materials, and in particular stressed silicon nitride dielectric materials. Stressed silicon nitride dielectric materials may be deposited using methods that are conventional in the semiconductor fabrication art. In particular, silicon nitride materials that are deposited using a chemical vapor deposition method may often have a stress level that may be adjusted as a function of a deposition temperature, or some other deposition variable. For example, a compressive stress from about 2000 to about 3500 MPa may be obtained within a silicon nitride material that is deposited at a temperature from about 400 to about 450 degrees centigrade.

FIG. 8 shows the results of etching back the first stressed material layer 30 to form a first stressed material plug 30′ located upon the liner layer 28 over the metal silicide gate electrode 19a. The first stressed material plug 30′ (or at least a portion thereof) is also laterally contained by the spacer layer 24 and thus aligned with the gate electrode 19a.

The first stressed material layer 30 may be etched back using any of several etch methods and materials. Non-limiting examples include wet chemical etch methods and materials, and dry plasma etch methods and materials. Wet chemical etch methods and materials are generally less common. More particularly common are dry plasma etch methods and materials that use an etchant gas composition that provides a specificity for the first stressed material layer 30 with respect to the liner layer 28.

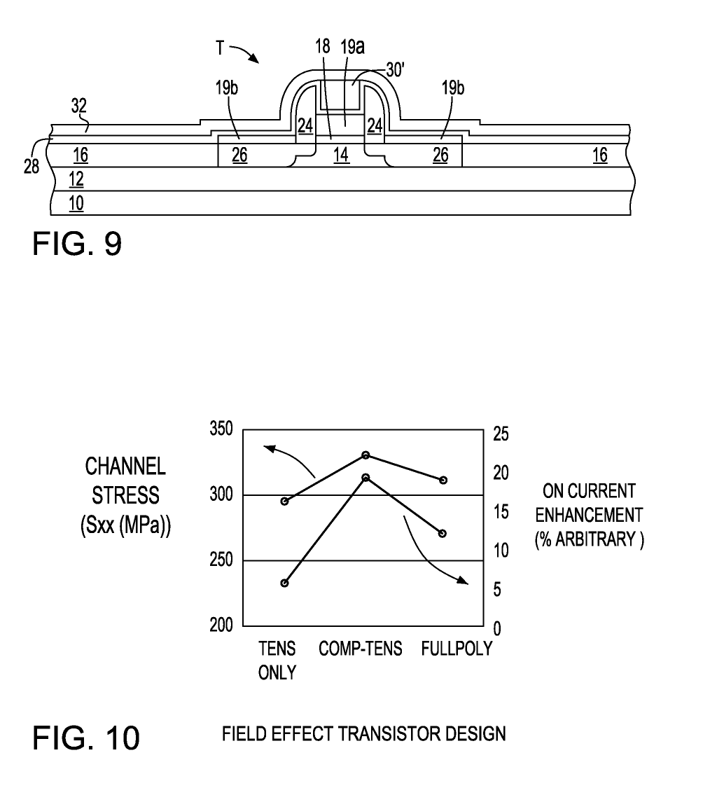

FIG. 9 shows a second stressed material layer 32 located upon the semiconductor structure of FIG. 8. The second stressed material layer 32 is located over, and particularly preferably upon, the first stressed material plug 30′. The second stressed material layer 32 may, similarly with the first stressed layer 30 that is illustrated in FIG. 7, also comprise a stressed dielectric material. Again, a stressed silicon nitride dielectric material is particularly common. Similarly with the first stressed material layer 30, such a stressed silicon nitride dielectric material may be deposited using a chemical vapor deposition method that provides that a stress level therein may be adjusted using a deposition temperature within the chemical vapor deposition method. Typically a deposition temperature from about 400 to about 550 degrees centigrade will provide a tensile stressed silicon nitride material having a tensile stress from about 1000 to about 2000 MPa.

FIG. 9 shows a schematic cross-sectional diagram of a semiconductor structure in accordance with an embodiment of the invention. The semiconductor structure comprises a semiconductor-on-insulator semiconductor substrate having a field effect transistor located within a surface semiconductor layer 14 of the semiconductor-on-insulator semiconductor substrate. Within the field effect transistor, a spacer layer 24 extends vertically above a metal silicide gate electrode 19a. A first stressed material plug 30′ (having a compressive stress for an n field effect transistor formed and located upon a (100) silicon or silicon-germanium surface semiconductor layer 14) is located upon the metal silicide gate electrode 19a. At least a portion of the first stressed material plug 30′ is laterally contained by the spacer layer 24. A second stressed material layer 32 having a second stress different (and typically opposite) the first stress is located upon the first stressed material plug 30′. At least a portion of the second stressed material layer 32 is not laterally contained by the spacer layer 24. Rather, the second stressed material layer 32 spans over portions of the surface semiconductor layer 14 that adjoin the channel region.

As will be seen within the context of the experimental data that follows, the use of the first stressed material plug 30′ in conjunction with the second stressed material layer 32 (i.e., each having a particular stress) provides for an enhanced channel stress within the field effect transistor T that is illustrated in FIG. 9.

FIG. 9 shows a graph of Channel Stress (Sxx) and On Current Enhancement for various configurations of a field effect transistor design including the configuration in accordance with the foregoing embodiment. Gate electrode configurations include (1) a metal silicide gate electrode having only a tensile second stressed material layer 32 (i.e., 1500 MPa) located thereover and not a compressive first stressed material plug 30′ (i.e., 3000 MPa) located thereover; (2) a metal silicide gate electrode having located thereover a stack comprising a compressive first stressed material plug 30′ and a tensile second stressed material layer 32 (i.e., a transistor structure fabricated in accordance with the embodiment) as illustrated in FIG. 9; and (3) a full height (i.e., same as spacer layer 24 height) doped polysilicon gate electrode having only a tensile second stressed material layer 32 located thereover and not a compressive first stressed material plug 30′ located thereover.

As is illustrated within the graph of FIG. 10, a transistor structure fabricated in accordance with the embodiment and the invention, and including a metal silicide gate electrode having: (1) a compressive first stressed material plug 30′ located thereupon and thereover; and (2) a tensile second stressed material layer 32 located further thereupon and thereover, has a particularly high lateral channel stress Sxx within a field effect transistor channel (that results in a desirable on-current enhancement. A field effect transistor fabricated using a full height polysilicon gate with a tensile second stressed material layer absent a compressive first stressed material plug provides a structure having a next higher lateral channel stress Sxx within a field effect transistor channel. Finally, a structure in accordance with the embodiment and the invention, but absent the first stressed material plug (which is a compressive stressed) has a lowest lateral channel stress Sxx.

The preferred embodiment is illustrative of the invention rather than limiting of the invention. Revisions and modifications may be made to methods, materials, structures and dimensions of a field effect transistor device in accordance with the preferred embodiment, while still providing a semiconductor structure in accordance with the invention, further in accordance with the accompanying claims.

What is claimed is:

1. A semiconductor structure comprising:
a semiconductor substrate including a gate electrode located over a channel region within the semiconductor substrate and a spacer layer located adjacent a sidewall of the gate electrode and rising vertically above the gate electrode;
a first stressed layer having a first stress located over the gate electrode, where at least a portion of the first stressed layer is laterally contained by the spacer layer; and
a second stressed layer having a second stress different than the first stress located over the first stressed layer, where at least a portion of the second stressed layer is not laterally contained by the spacer layer.

2. The semiconductor structure of claim 1 wherein the semiconductor substrate comprises a bulk semiconductor substrate.

3. The semiconductor structure of claim 1 wherein the semiconductor substrate comprises a semiconductor-on-insulator substrate.

4. The semiconductor structure of claim 1 wherein the first stressed layer is compressive stressed and the second stressed layer is tensile stressed.

5. The semiconductor structure of claim 4 wherein:
the semiconductor substrate has a (100) crystallographic orientation surface and a <110> current flow direction; and
the gate electrode comprises an n-field effect transistor.

6. A method for fabricating a semiconductor structure comprising:
forming a gate electrode over a channel region within a semiconductor substrate and forming a spacer layer adjacent the gate electrode and rising vertically above the gate electrode;
forming a first stressed layer having a first stress over the gate electrode, at least a portion of the first stressed layer being laterally contained by the spacer layer; and
forming a second stressed layer having a second stress different than the first stress over the first stressed layer, at least a portion of the second stressed layer not being laterally contained by the spacer layer.

7. The method of claim 6 wherein the forming the gate electrode over the channel region uses a bulk semiconductor substrate.

8. The method of claim 6 wherein the forming the gate electrode over the channel region uses a semiconductor-on-insulator semiconductor substrate.

9. The method of claim 6 wherein the first stress is opposite the second stress.

10. The method of claim 6 wherein the forming the first stressed layer provides that the first stressed layer is completely laterally contained by the spacer layer.

11. The method of claim 6 wherein the forming the second stressed layer provides that no portion of the second stressed layer is laterally contained by the spacer layer.

12. A method for fabricating a semiconductor structure comprising:
forming over a channel region within a semiconductor substrate a gate electrode stack comprising a gate electrode, a sacrificial layer located upon the gate electrode and a spacer layer located adjacent a sidewall of the gate electrode and the sacrificial layer;
stripping the sacrificial layer from the gate electrode so that the spacer layer rises vertically above the gate electrode;
forming a first stressed layer having a first stress over the gate electrode, at least a portion of the first stressed layer being laterally contained by the spacer layer; and
forming a second stressed layer having a second stress different than the first stress over the first stressed layer, at least a portion of the second stressed layer not being laterally contained by the spacer layer.

13. The method of claim 12 wherein the forming the gate electrode stack uses a bulk semiconductor substrate.

14. The method of claim 12 wherein the forming the gate electrode stack uses a semiconductor-on-insulator substrate.

15. The method of claim 12 wherein the gate electrode comprises a silicon gate electrode.

16. The method of claim 15 further comprising forming a metal silicide gate electrode from the silicon gate electrode after stripping the sacrificial layer and prior to forming the first stressed layer over the gate electrode.

17. The method of claim 16 wherein the forming the metal silicide gate electrode uses a salicide method.

18. The method of claim 17 wherein the salicide method uses a metal silicide forming metal selected from the group consisting of nickel, cobalt, platinum, titanium, tungsten, tantalum, vanadium, hafnium, erbium, ytterbium, and rhenium metal silicide forming metals.

19. The method of claim 12 wherein the forming the gate electrode uses a (100) silicon or silicon-germanium alloy semiconductor substrate and the gate electrode comprises an n field effect transistor.

20. The method of claim 19 wherein the first stress is a compressive stress and the second stress is a tensile stress.
